(19) United States
(12) Patent Application Publication
(10) Pub. No.: US 2014/0266361 A1
(43) Pub. Date: Sep. 18, 2014

(54) DUTY CYCLE CORRECTION CIRCUIT

(71) Applicant: TEXAS INSTRUMENTS INCORPORATED, Dallas, TX (US)

(72) Inventors: Siddharth Shashidharan, Bangalore (IN); Sumantra Seth, Bangalore (IN); Ravi Jithendra Mehta, Bangalore (IN); Biman Chattopadhyay, Bangalore (IN); Sujoy Chinmoy Chakravarty, Bangalore (IN)

(73) Assignee: Texas Instruments Incorporated, Dallas, TX (US)

(21) Appl. No.: 13/886,637

(22) Filed: May 3, 2013

(30) Foreign Application Priority Data
Mar. 15, 2013 (IN) 1142/CHE/2013

(51) Int. Cl. H03K 3/017

(52) U.S. Cl. CPC H03K 3/017
USPC 327/175

(57) ABSTRACT

In an embodiment, a duty cycle correction circuit comprises a first set of inverters connected in series, a first filter, a first feedback circuit and a second feedback circuit. A first inverter in the series is configured to receive a clock signal and a last inverter in the series is configured to provide a first output clock signal. The first filter is configured to generate a first direct current (DC) voltage signal at an output of the first filter. The first feedback circuit is configured to control a rise time of a signal transition at an output terminal of the first inverter to control a duty cycle of the first output clock cycle. The second feedback circuit is configured to control a fall time of the signal transition at the output terminal of the first inverter to control the duty cycle of the first output clock cycle.

### TECHNICAL FIELD

The present disclosure generally relates to duty cycle correction circuits.

### BACKGROUND

In accordance with an exemplary scenario, digital or mixed signal circuits (such as microprocessor units) include sequential elements that utilize clock signals (generated from clock sources) for their operation. Due to setup and hold time parameters associated with these sequential elements, the pulse width and duty cycle of the applied clock signals are important parameters for the performance of the various circuits, such as the circuits within the microprocessor units. The clock signals for the microprocessor units may be derived from a clock source capable of generating high frequency clock signals. However, in so much as the frequency of the clock signal is high, the duty cycle of the generated clock signal may deviate considerably from a 50 percent duty cycle. Such an uncontrolled duty cycle of the clock signal is more pronounced in circuit regions positioned relatively far from the clock source.

### SUMMARY

This summary is provided to introduce a selection of concepts in a simplified form that are further described below in the detailed description. This Summary is not intended to identify key or essential features of the claimed subject matter, nor is it intended to be used as an aid in determining the scope of the claimed subject matter.

Various circuits for duty cycle correction circuit are disclosed. In an embodiment, a duty cycle correction circuit comprises a first set of inverters coupled or connected in series. Each inverter in the series is configured by a first transistor and a second transistor. A first inverter in the series comprising an output terminal is configured to receive a clock signal, a signal transition at the output terminal having a rise time and a fall time, and a last inverter in the series is configured to generate a first output clock signal having a first corrected duty cycle at an output of the last inverter. The duty cycle correction circuit comprises a first filter coupled with the output of the last inverter and the first filter is configured to generate a first direct current (DC) voltage signal at an output of the first filter. The first DC voltage signal is generated in response to the first output clock signal received from the output of the last inverter.

In an embodiment, the duty cycle correction circuit further comprises a first feedback circuit and a second feedback circuit. The first feedback circuit is coupled with the output of the first filter and the first transistor of the first inverter. The first feedback circuit is configured to control the rise time, based on a comparison of the first DC voltage signal and a first threshold voltage, to thereby correct duty cycle. The second feedback circuit is coupled with the output of the filter and the second transistor of the first inverter. The second feedback circuit is configured to control the fall time, based on a comparison of the first DC voltage signal and a second threshold voltage, to thereby further correct the duty cycle.

In one embodiment, a duty cycle correction circuit comprises a first inverter and a second inverter connected in series. Each of the first and second inverters comprises a first transistor and a second transistor. The first inverter comprising an output terminal and is configured to receive a clock signal, a signal transition at the output terminal having a rise time and a fall time, and the second inverter is configured to generate a first output clock signal having a first corrected duty cycle at an output of the second inverter. The duty cycle correction circuit comprises a first filter coupled with the output of the second inverter. The first filter is configured to generate a first direct current (DC) voltage signal at an output of the first filter in response to the first output clock signal. The duty cycle correction circuit further comprises a first amplifier and a third transistor. The first amplifier comprises a first input terminal, a second input terminal and a first output terminal. The first input terminal is coupled with a first threshold voltage and the second input terminal is coupled with the output of the first filter to receive the first DC voltage signal. The third transistor comprises a first terminal, a second terminal and a third terminal. The first terminal is coupled with the first output terminal of the first amplifier and the second terminal is coupled with a power supply terminal and the third terminal is coupled with the first transistor of the first inverter to provide a power supply voltage to the first transistor of the first inverter. The third transistor increases the rise time of the signal transition at the output terminal of the first inverter.

The duty cycle correction circuit further comprises a second amplifier and a fourth transistor. The second transistor comprises a third input terminal, a fourth input terminal and a second output terminal. The third input terminal is coupled with a second threshold voltage and the fourth input terminal is coupled with the output of the first filter to receive the first DC voltage signal. The fourth transistor comprises a fourth terminal, a fifth terminal and a sixth terminal. The fourth terminal is coupled with the second output terminal of the second amplifier, the fifth terminal is coupled with a voltage ground terminal and the sixth terminal is coupled with the second transistor of the first inverter. The fourth transistor increases the fall time and further correct the duty cycle.

In another embodiment, a duty cycle correction circuit comprises a first stage and a second stage. The first stage is configured to generate a first output clock signal having a first corrected duty cycle in response to a clock signal. The first stage comprises a first set of inverters connected in series, a first filter, a first feedback circuit and a second feedback circuit. A first inverter in the series is configured to receive the clock signal and a last inverter in the series is configured to provide the first output clock signal at an output of the last inverter. The first filter is coupled with the output of the last inverter. The first filter is configured to generate a first direct current (DC) voltage signal at an output of the first filter in response to the first output clock signal received from the output of the last inverter. The first feedback circuit is coupled between the output of the first filter and a first transistor of the first inverter. The second feedback circuit is coupled between the output of the first filter and a second transistor of the first inverter. The first feedback circuit is configured to control a rise time of a signal transition at an output terminal of the first inverter based on a comparison of the first DC voltage signal and a first threshold voltage. The second feedback circuit is configured to control a fall time of the signal transition based on a comparison of the first DC voltage signal and a second threshold voltage for generating the first output clock signal having the first corrected duty cycle.

The second stage is configured to receive the first output clock signal and generate a second output clock signal having a second corrected duty cycle. The second stage comprises a second set of inverters coupled in series, a second filter and a third feedback circuit. The first inverter of the second set of inverters in the series receiving the first output clock signal and a last inverter of the second set of inverters in the series is configured to provide the second output clock signal at an output of the last inverter of the second set of inverters. The second filter is coupled with the output of the last inverter of the second set of inverters. The second filter is configured to generate a second DC voltage signal at an output of the second filter in response to the second output clock signal received from the output of the last inverter of the second set of inverters. The third feedback circuit is configured to control a rise time and a fall time of a signal transition at an output terminal of the first inverter of the second set of inverters based on a comparison of the second DC voltage signal and a third threshold voltage for generating the second output clock signal having the second corrected duty cycle.

### BRIEF DESCRIPTION OF THE FIGURES

FIG. 1 illustrates a schematic representation of an implementation of an exemplary duty cycle correction circuit in an Integrated Circuit (IC) in accordance with an exemplary scenario;

FIG. 2 illustrates a schematic circuit diagram of a first exemplary duty cycle correction circuit in accordance with an embodiment; and

FIGS. 3A and 3B illustrate a schematic circuit diagram of a second exemplary duty cycle correction circuit in accordance with an embodiment;

### DETAILED DESCRIPTION

In the following detailed description, numerous specific details are set forth in order to provide a thorough understanding of the present technology. However, the present technology may be practiced without these specific details. In other instances, well-known methods, procedures, components, and circuits have not been described in detail so as to not unnecessarily obscure aspects of the exemplary embodiments presented herein. Moreover, it is noted that structures and devices are shown in block diagram form in order to avoid obscuring the disclosure.

Reference in this specification to “one embodiment” or “an embodiment” means that a particular feature, structure, or characteristic described in connection with the embodiment is included in at least one embodiment of the disclosure. The appearance of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various parameters are described that may be parameters for some embodiments but not for other embodiments.

FIG. 1 shows an implementation of an exemplary duty cycle correction circuit in a System on Chip (SoC) or an Integrated Circuit (IC) 100 in accordance with an exemplary scenario. The IC 100 comprises a Phase Locked Loop (PLL) 110, a duty cycle correction circuit (DCC) 120 and a circuit such as a microprocessor unit (MPU) 130 that require a clock signal derived from the PLL 110. For the purposes of this description, the ‘duty cycle’ of a clock signal refers to a ratio of a time corresponding to high pulse level (Ton) and a time corresponding to clock period (Tperiod) of the clock signal.

The PLL 110 generates a high frequency clock signal, for example, a clock signal of 1 Gigahertz (GHz) to 2 GHz. However, the duty cycle of the high frequency clock signal may be uncontrolled and may not be equal to 50 percent. In one implementation shown in FIG. 1, the PLL 110 may include a divider circuit 115 that can provide a clock signal of 50 percent duty cycle to the MPU 130, such as by dividing the clock signal generated by the PLL 110 by two. However, in this implementation, the PLL 110 is required to generate a clock signal at twice of frequency of a clock signal required by the MPU 130. For instance, for providing a 1.5 GHz clock to the MPU 130, the PLL 110 will be required to generate a clock signal of 3 GHz frequency. However, as the frequency of the clock signal increases, generation of such clock signal is difficult and also requires a significant current consumption.

In one implementation, in a scenario of the high frequency clock signal (for example, between 1 GHz 2 GHz) with the uncontrolled duty cycle, the DCC 120 may be used to correct the duty cycle of the high frequency clock signal, and the corrected clock signal may be provided to the MPU 130. The DCC 120 adds a delay to a rising or a falling edge of the clock signal which corrects the duty cycle of the clock signal to achieve the 50 percent duty cycle. The clock signal with the controlled duty cycle (i.e., 50%) is provided to the MPU 130 without reducing the frequency of the clock signal generated by the PLL 110. In some implementations, both the divider circuit 115 and the DCC 120 may be connected together with the PLL 110 and the output of the divider circuit 115 and the DCC 120, both, with controlled duty cycle (50%) are connected to a multiplexer 140. Depending upon the application and the requirement of the MPU 130, the clock signal with either low frequency or high frequency can be selected through the multiplexer 140 (using ‘Clk Select 125’) and the desired clock signal can be provided to the MPU 130.

Various embodiments of the present technology provide circuit designs of duty cycle correction circuits. These embodiments are described with reference to subsequent figures.

An exemplary embodiment of a duty cycle correction circuit is shown in FIG. 2, FIG. 2 represents a first exemplary duty cycle correction circuit 200 (hereinafter referred to as ‘circuit 200’) that may be an example of the duty cycle correction circuit 120 described in reference to FIG. 1. The circuit 200 includes a first set of inverters, for example, inverters 210 and 220 connected in series. Each of the inverter 210 and 220 is configured by two transistors, for example, a PMOS transistor and a NMOS transistor. The inverter 210 is shown as configured by a PMOS transistor 212 and a NMOS transistor 214. The first inverter of the series, for example, the inverter 210 receives a clock signal (e.g., CLK_IN 202). The CLK_IN 202 may have a poor duty cycle, for example, a duty cycle other than 50 percent. In an embodiment, the input clock signal (e.g., the CLK_IN 202) is received at an input of the inverter 210, and the inverted clock signal (at an output terminal 215 of the inverter 210) is again inverted by the inverter 220 to generate a first output clock signal (e.g., CLK_OUT 204) at an output 222 of the inverter 220. The circuit 200 is configured to correct the duty cycle of the CLK_IN 202 such that the CLK_OUT 204 has a first corrected duty cycle.

The circuit 200 includes a first feedback circuit 230 and a second feedback circuit 260 for controlling the generation of the CLK_OUT 204 such that the CLK_OUT 204 has the first corrected duty cycle (for example, the duty cycle lying in a pre-defined range). The circuit 200 includes a filter 250 (first filter) coupled with the output 222 of the inverter 220. The filter 250 is configured to generate a direct current (DC) signal 254 (first DC voltage signal) at an output 252 of the filter 250. The DC signal 254 is generated in response to the CLK_OUT 204 received from the output 222 of the inverter 220. In one form, the filter 250 may be a low pass filter configured by one or more resistors and capacitors, such that at the output 252, the DC signal 254 corresponding to the CLK_OUT 204 is generated.

The first feedback circuit 230 and the second feedback circuit 260 are coupled with the output 252 to receive the DC signal 254, and based on a comparison of the DC signal 254 to a first threshold voltage 255 and a second threshold voltage 256, respectively, rise and fall transitions at the output terminal (sec, 215) of the inverter 210 is controlled. For instance, if the rise and/or fall transitions at the output terminal 215 of the inverter 210 is changed, that results into changes in the Ton and Toff time of the CLK_OUT 204. The feedback circuits 230 and 260 are configured to control the CLK_OUT 204 such that the duty cycle of the CLK_OUT 204 is in the pre-defined range. For example, the predefined range may be between 50-Δ and 50+Δ, where Δ may be any small integer or a fraction number. In an example, the predefined range may include a duty cycle between 47 percent to 53 percent. However, the range of 47 percent to 53 percent should not be considered as limiting, and serves as an example only.

The feedback circuit 230 includes an amplifier 235 (first amplifier) and a third transistor such as PMOS transistor 240. In an embodiment, the amplifier 235, without limiting the scope of the present technology, is configured by an operational amplifier. An input terminal 236, for example, a non-inverting terminal (first input terminal) of the amplifier 235 is coupled to the first threshold voltage 255 and an input terminal 237, for example, an inverting terminal (second input terminal) of the amplifier 235 is coupled to the output 252 of the filter 250. The PMOS transistor 240 is coupled with a power supply terminal (shown by ‘VDD’), an output 238 (first output terminal) of the amplifier 235 and the PMOS transistor 212. For instance, a gate terminal 242 (first terminal) of the PMOS transistor 240 receives a signal from the output 238 of the amplifier 235, a source terminal (the second terminal) 244 is coupled with the power supply terminal (shown as VDD) and a drain terminal 246 (the third terminal) is coupled with the transistor 212. It should be noted that as the PMOS transistor 240 is configured in a charging path of the transistor 212 (e.g., connected between the VDD and a source of the PMOS transistor 212), the operation of the PMOS transistor 240 can control the rise time (a time involved in signal transition from low to high) at the output terminal 215. For instance, as the gate voltage (at the terminal 242) increases, the PMOS transistor 240 becomes weaker in conduction thereby slowing the charging of the output terminal 215 to VDD. It should be noted that the PMOS transistor 240 provided in the supply path (i.e., the charging path) of the inverter 210 acts as a current controlling resistance and its resistance is controlled by the output voltage of the amplifier 235. Accordingly, based on the voltage at the output 238 of the amplifier 235, the transistor 240 controls a rising clock edge at the output terminal 215 of the inverter 210, that is again inverted by the inverter 220 to generate the CLK_OUT 204.

The feedback circuit 260 includes an amplifier 265 (second amplifier) and a fourth transistor such as a NMOS transistor 270. In an embodiment, the amplifier 265, without limiting the scope of the present technology, is configured by an operational amplifier. An input terminal 266, for example, a non-inverting terminal (third input terminal) of the amplifier 265 is coupled to the second threshold voltage 256 and an input terminal 267, for example, an inverting terminal (fourth input terminal) of the amplifier 265 is coupled to the output 252 of the filter 250. The NMOS transistor 270 is coupled with a voltage ground terminal (shown as ‘VGND’), an output 268 (second output terminal) of the amplifier 265 and the NMOS transistor 214. For instance, a gate terminal 272 (fourth terminal) of the NMOS transistor 270 receives a signal from the output 268 of the amplifier 265, a source terminal (the fifth terminal) 274 is coupled with the VGND and a drain terminal 276 (the sixth terminal) is coupled with the transistor 214. It should be noted that as the NMOS transistor 270 is configured in a discharging path of the transistor 214 (e.g., connected between the VGND and a source of the NMOS transistor 214), the operation of the NMOS transistor 270 can affect the fall time at the output terminal 215, and the signal transition from high to low at the output terminal 215 can be accordingly controlled. For instance, if the gate voltage (at the terminal 272) decreases, the NMOS transistor 270 becomes weaker in conduction thereby slowing the discharging of the output terminal 215 to a voltage ground reference (VGND). It should be noted that the NMOS transistor 270 provided in the ground path (i.e., the discharging path) of the inverter 210 acts as a current controlling resistance and its resistance is controlled by the output voltage of the amplifier 265. Accordingly, based on the voltage at the output 268 of the amplifier 265, the transistor 270 controls a falling clock edge at the output terminal 215 of the inverter 210, that is again inverted by the inverter 220 to generate the CLK_OUT 204. It should be noted that the third transistor 240 and the fourth transistor 270 are shown as the PMOS and NMOS transistors, respectively, in the embodiment of FIG. 2, however, it should not be considered as limiting to the scope of the present technology. In alternate embodiments, examples of the transistors 240 and 270 may also include Bipolar Junctions Transistors (BJTs) or other Field Effect Transistors (FETs).

The circuit 200 further includes a first capacitor 280 for coupling the gate terminal 242 (or the output 238 of the amplifier 235) of the PMOS transistor 240 to the power supply terminal (VDD), for achieving a good noise immunity. Similarly, the circuit 200 also includes a second capacitor 290 for coupling the gate terminal 272 of the NMOS transistor 270 to the voltage ground terminal (VGND), for achieving a good noise immunity. By using the capacitors 280 and 290, it may be ensured that a loop created by the first feedback circuit 230 and a loop created by the feedback circuit 260 are not affected by noise generated therein, and any loop gain does not cause the duty cycle of the CLK_OUT 204 to vary.

The operation of the circuit 200 can be explained with an example. In this example, it may be assumed that the first threshold voltage 255 is 47 percent of a power supply voltage (e.g., VDD), for example, 0.47*VDD, and the second threshold voltage 256 is 53 percent of the power supply voltage (e.g., VDD), for example, 0.53*VDD. If the duty cycle of the CLK_IN 202 is less than 47 percent, for example, 33 percent. Initially, the CLK_OUT 204 also has the same duty cycle of 33 percent, and the filter 250 provides the DC average of the CLK_OUT 204 (e.g., 0.33*VDD) at the output 252 of the filter 250. As the output 252 is coupled to the non-inverting terminal 237 of the amplifier 235, and the first threshold voltage 255 of 0.47*VDD is coupled with the non-inverting terminal 236 of the amplifier 235. Due to the difference in the signal voltages at the terminals 236 and 237, the output 238 of the amplifier 235 increases (i.e., the voltage at the gate terminal 242 increases), thereby weakening the PMOS transistor 240. Such increase in the gate voltage causes a slower charging of the output terminal 215 (i.e., a delay in rise time of a signal transition from low to high). As the CLK_OUT 204 is inverse of a signal present at the output terminal 215, therefore there is an increase in the ‘Ton’ time of the CLK_OUT 204. It should be noted that the ‘Ton’ time of the CLK_OUT 204 keeps on increasing till the DC average of the CLK_OUT 204 is equal to 0.47*VDD, through the feedback circuit 230. It should further be noted that as long as the DC voltage signal is less than or equal to 0.47*VDD, the NMOS transistor 270 remains in linear mode, as the amplifier output (268) is saturated. As the non-inverting terminal 266 of the amplifier 265 is fed with the 0.53*VDD voltage (that is significantly more than the DC voltage signal of the CLK_OUT 204), it causes the NMOS transistor 270 to remain in linear mode. Accordingly, there is no impact on the fall time (a signal transition from high to low) at the output terminal 215 due to the feedback circuit 260. In this manner, as the duty cycle of the CLK_OUT 204 goes below 47 percent, the feedback circuit 230 is configured to correct the duty cycle of the CLK_OUT 204 to 47 percent and during this time the feedback circuit 260 does not have impact on the duty cycle of the CLK_OUT 204.

In another example, if the duty cycle of the CLK_IN 202 is more than 53 percent (for example, 70 percent), initially the CLK_OUT 204 also has a duty cycle of 70 percent. The filter 250 provides the DC average of the CLK_OUT 204 (e.g., 0.7*VDD) at the output 252 of the filter 250. As the output 252 is coupled to the inverting terminal 267 of the amplifier 265, and the second threshold voltage 256 of 0.53V is coupled with the non-inverting terminal 266 of the amplifier 265. Due to the difference in the signal voltages at the terminals 266 and 267, the output 268 of the amplifier 265 decreases (i.e., the voltage at the gate terminal 272 decrease) thereby weakening the NMOS transistor 270. Such decrease in the gate voltage causes a slower discharging of the output terminal 215 (i.e., a delay in fall time of a signal transition from high to low). As the CLK_OUT 204 is inverse of the output terminal 215, therefore there is a decrease in the ‘Ton’ time of the CLK_OUT 204. It should be noted that the ‘Ton’ time of the CLK_OUT 204 keeps on decreasing till the DC average of the CLK_OUT 204 is equal to 0.53*VDD (based on the feedback circuit 260). It should further be noted that as long as the DC voltage signal is more than or equal to 0.53*VDD, the PMOS transistor 240 remains in a linear mode. As the non-inverting terminal 236 of the amplifier 235 is fed with the 0.47*VDD voltage (that is significantly less than the DC voltage signal of the CLK_OUT 204), it causes the PMOS transistor 240 to remain in linear mode. Accordingly, there is no impact on the rise time (a signal transition from low to high) at the output terminal 215 due to the feedback circuit 230. In this manner, as the duty cycle of the CLK_OUT 204 goes above 53 percent, the feedback circuit 260 is configured to correct the duty cycle of the CLK_OUT 204 to 53 percent, and during this time the feedback circuit 230 does not have impact on the duty cycle of the CLK_OUT 204.

It should be noted that the feedback circuits 230 and 260 are configured to correct the duty cycle of the CLK_IN 202, such that the duty cycle of the CLK_OUT 204 lies in a pre-determined range, for example, between 47 percent to 53 percent. If the duty cycle of the CLK_IN 202 lies in a first range, for example, between 25 percent to 47 percent, the feedback circuit 230 causes to correct the duty cycle of the CLK_OUT 204 as 47 percent. Further, if the duty cycle of the CLK_IN 202 lies in a second range, for example, between 53 percent to 75 percent, the feedback circuit 260 causes to correct the duty cycle of the CLK_OUT 204 as 53 percent. It should also be noted that if the duty cycle of the CLK_IN 202 lies in a third range, for example, between 47 percent to 53 percent, the feedback circuits 230 and 260 may not have any impact on the duty cycle of the CLK_OUT 204. For instance, if the DC signal received from the filter 250 is between 0.47*VDD and 0.53*VDD, the transistors 240 and 270 remain in the linear mode, thereby causing same duty cycle for the CLK_OUT 204 as of the CLK_IN 202. In some implementations, values of the first threshold voltage 255 and the second threshold voltage 256 may be other than 0.47*VDD and 0.53*VDD, for example, 0.49*VDD and 0.51*VDD, and the like.

In some implementations of the present technology, a next stage of a duty cycle correction circuit may be used that can receive the CLK_OUT 204 as input and perform a duty cycle correction of the CLK_OUT 204 to generate a clock signal having 50 percent duty cycle. As the CLK_OUT 204 received from the circuit 200 is already duty cycle corrected (for example, the duty cycle lying between 50-Δ and 50+Δ), it may be further corrected using a single feedback circuit to achieve a 50 percent duty cycle. Some embodiments of such implementations of the present technology are further described in reference to FIGS. 3A and 3B.

FIGS. 3A and 3B provide a second exemplary duty cycle correction circuit 300 in accordance with another embodiment of the present technology. The circuit 300 includes a first stage 301 (shown in FIG. 3A) and a second stage 351 (shown in FIG. 3B) for performing a duty cycle correction of a clock signal 302.

The first stage 301 is configured to generate a first output clock signal (for example, ‘CLK_OUT1 304’) in response to the clock signal 302. The CLK_OUT1 304 is an output clock of the first stage 301 that has a duty cycle lying in a pre-defined range (the first corrected duty cycle), for example, between a first threshold percent and a second threshold percent. An example of the first stage 301 is the circuit 200, as described in reference with FIG. 2. As already described above, if the values of the first threshold voltage 255 and the second threshold voltage 256 are 0.47*VDD and 0.53*VDD, respectively, the CLK_OUT1 304 will have a duty cycle lying between 47 percent to 53 percent. For instance, if the duty cycle of the clock signal 302 (CLK_IN 302) is in a first range, for example, between 25 percent to 47 percent, the duty cycle of the output clock of the first stage (CLK_OUT1 304) is corrected such that the duty cycle of the CLK_OUT1 304 is 47 percent. Further, if the duty cycle of the clock input 302 is in a second range, for example, between 53 percent to 75 percent, the CLK_OUT1 304 is corrected such that the duty cycle of the CLK_OUT1 304 is 53 percent. In an example, the first stage 301 provides the CLK_OUT1 304 that has a same duty cycle of the CLK_IN 302, if the duty cycle of the CLK_IN 302 lies between the 47 percent and the 53 percent. Accordingly, in an example, the first stage 301 is configured to generate the CLK_OUT1 304 having a duty cycle between the pre-defined range (for example, between 47 percent to 53 percent).

The second stage 351 is configured to receive the CLK_OUT1 304 (as input) which has a duty cycle in the pre-defined range, for example, between 47 percent to 53 percent. The second stage 351 is configured to correct the duty cycle of the CLK_OUT1 304 such that an output clock signal (shown as CLK_OUT 306) has a duty cycle of 50 percent.

The second stage 351 includes a second set of inverters, for example, inverters 310 and 320 connected in series. Each of the inverter 310 and 320 is configured by two transistors, for example, a PMOS transistor and a NMOS transistor. The inverter 310 (third inverter) is shown as configured by a PMOS transistor 312 and a NMOS transistor 314. The first inverter of the series, for example, the inverter 310 receives the first output clock signal (e.g., CLK_OUT1 304) of the first stage 310. The CLK_OUT1 304 has a duty cycle lying in the pre-defined range. In an embodiment, the CLK_OUT1 304 is received at an input of the inverter 310, and the inverted clock signal is again inverted by the inverter 320 (fourth inverter) to generate a second output clock signal (e.g., CLK_OUT 306) at an output 322 of the inverter 320. The circuit 300 is configured to correct the duty cycle of the CLK_OUT1 304 such that the CLK_OUT 306 has a 50 percent duty cycle (a second corrected duty cycle).

The second stage 351 includes a feedback circuit 330 for controlling the generation of the CLK_OUT 306 such that the CLK_OUT 306 has the 50 percent duty cycle. The circuit 351 includes a filter 350 (second filter) coupled with the output 322 of the inverter 320. The filter 350 is configured to generate a direct current (DC) signal 354 (second DC voltage signal) at an output 352 of the filter 350. The DC signal 354 is generated in response to the CLK_OUT 306 received from the output 322 of the inverter 320. In one form, the filter 350 may be a low pass filter configured by one or more resistors and capacitors, such that at the output 352, the DC signal 354 corresponding to the CLK_OUT 306 is generated.

The feedback circuit 330 includes an amplifier 335 (third amplifier), a transistor 340 (fifth transistor) and a transistor 370 (sixth transistor). Without limiting to the scope of the present technology, in an embodiment, the amplifier 335 is configured by an operational amplifier. An input terminal 336, for example, a non-inverting terminal (fifth input terminal) of the amplifier 335 is coupled to a third threshold voltage 355 and an input terminal 337, for example, an inverting terminal (sixth input terminal) of the amplifier 335 is coupled to the output 352 of the filter 350. In an embodiment, the third threshold voltage 355 may be a constant voltage, such as half of the power supply voltage (e.g., VDD/2). However, in some forms, the third threshold voltage may also be a function of the power supply voltage VDD, and depending upon the applications and requirement of the duty cycle, it may be selected. It should also be noted that even the first and second threshold voltages used in the first stage 301 may also be a function of the VDD, and depending upon the applications and requirement of the duty cycle, their values may be selected.

in an embodiment, the transistor 340 is a PMOS transistor and is coupled in a charging path of the transistor 312. A gate terminal 342 (seventh terminal) of the PMOS transistor 340 receives a signal from an output 338 of the amplifier 335, a source terminal (eighth terminal) 344 is coupled with the VDD and a drain terminal 346 (ninth terminal) is coupled with the transistor 312. It should be noted that as the PMOS transistor 340 is configured in a charging path of the transistor 312 (e.g., connected between VDD and a source of the PMOS transistor 312), the operation of the PMOS transistor 340 can control the rise time (a time involved in signal transition from low to high) at an output terminal 315 of the inverter 310. For instance, as the gate voltage (at the terminal 342) increases, the PMOS transistor 340 becomes weaker in conduction thereby slowing the charging of the output terminal 315 from a low voltage to VDD. It should be noted that the PMOS transistor 340 provided in the supply path (i.e., the charging path) of the inverter 310 acts as a current controlling resistance and its resistance is controlled by the output voltage of the amplifier 335. Accordingly, based on the voltage at the output 338 of the amplifier 335, the transistor 340 slows down a rising clock edge at the output terminal 315 that is again inverted by the inverter 320 to generate the CLK_OUT 306.

In an embodiment, the transistor 370 is a NMOS transistor and is coupled in a discharging path of the transistor 314. A gate terminal 372 (tenth terminal) of the NMOS transistor 370 receives a signal from the output 338 of the amplifier 335, a source terminal (eleventh terminal) 376 is coupled with the VGND and a drain terminal 374 (twelfth terminal) is coupled with the transistor 314. It should be noted that as the NMOS transistor 370 is configured in the discharging path of the transistor 314 (e.g., connected between the VGND and a source of the NMOS transistor 314), the operation of the NMOS transistor 370 can control the fall time (a time involved in signal transition from high to low) at the output terminal 315. For instance, as the gate voltage (at the terminal 372) decreases, the NMOS transistor 370 becomes weaker in conduction thereby slowing down the discharging of the output terminal 315 to VGND. It should be noted that the NMOS transistor 370 provided in the ground path (i.e., the discharging path) of the inverter 310 acts as a current controlling resistance and its resistance is controlled by the output voltage of the amplifier 235. Accordingly, based on the voltage at the output 338 of the amplifier 335, the transistor 370 controls a falling clock edge at the output terminal 315, that is again inverted by the inverter 320 to generate the CLK_OUT 306. The second stage 351 may also include a capacitor 380 for coupling the output terminal 338 to the ground supply in order to perform noise suppression. It should be noted that the transistors 240 and 270 are shown as the PMOS and NMOS transistors, respectively, in the embodiment of FIG. 3B, however, it should not be considered as limiting to the scope of the present technology. In alternate embodiments, examples of the transistors 240 and 270 may also include Bipolar Junctions Transistors (BJTs) or other Field Effect Transistors (FETs).

The operation of the circuit 300 can be explained with an example. In this example, it may be assumed that the duty cycle of the CLK_OUT1 304 (provided by the first stage 301) is in the pre-defined range, for example, between 47 percent to 53 percent. As the non-inverting terminal 336 of the amplifier 335 is fed with the third threshold voltage 355 (i.e., 0.5*VDD), the amplifier 335 generates a signal at the output 338 in response to a difference of the DC signal received from the output 352 and the 0.5*VDD voltage. Accordingly, if the duty cycle of the CLK_OUT1 304 is 48 percent, the DC signal 354 is 0.48*VDD, and the signal generated at the output 352 corresponds to a difference of the 0.5*VDD and 0.48*VDD. Similarly, if the duty cycle of the CLK_OUT1 304 is 52 percent, the DC signal 354 is 0.52*VDD, and the signal generated at the output 352 corresponds to a difference of the 0.5*VDD and 0.52*VDD. Further, based on the signal at the output 338 of the amplifier 335, one of the transistors 340 and 370 is current starved. This enables a slow rise/fall time at the output terminal 315 of the inverter 310. For instance, depending upon the voltage at the output 338 of the amplifier 335, either a rising edge or falling edge is controlled to change the duty cycle to 50 percent at the output terminal 315. The inverter 320 further provides to a clean clock signal 306 having 50 percent duty cycle.

It should be noted that various embodiments of the present technology may be configured using different combination/arrangements of various circuit elements including the components shown in the FIGS. 2 and 3A and 3B, or otherwise not shown therein. In one embodiment, each of the first stage and the second stage may include only one inverter or odd number of inverters (ensuring the feedback remains negative) and an input clock received at the first stage may be corrected with a 50 percent duty cycle at an output of the second stage. For instance, in this embodiment, output of the single inverter (or the last inverter of odd number of inverters) of the first stage may be coupled to a first filter of the first stage. Further, using the first and second feedback circuits, a first corrected clock signal may be generated at the output of the first stage that has a first corrected duty cycle (for example, between 47 percent to 50 percent). Further, the first corrected output signal is provided to the single inverter (or the odd number of inverters) of the second stage, that may further generate the second corrected clock signal having a duty cycle of 50 percent. It should also be noted that only two inverters are shown in each of the first stage and the second stage for the exemplary purposes, and there may be more than two (even, odd or a combination) inverters present in the each stage, and still the corrected output clock signal of 50 percent duty cycle may be generated.

Without in any way limiting the scope, interpretation, or application of the claims appearing below, a technical effect of one or more of the exemplary embodiments disclosed herein is to provide analog implementations to perform duty cycle correction of clock signals. Various embodiments of the duty cycle correction circuits are not prone to power supply noise, and can operate over a large range of VDD supply voltage such as 0.9 V to 1.8 V, as gains in the loops (formed by the feedback circuits) have no adverse effect because of the supply/ground coupling capacitors (such as capacitors 280 and 290). Various embodiments of the present technology provide duty cycle correction for a large range of duty cycle distortion, by correcting the duty cycle in two stages. For example, in the first stage, the duty cycle of the clock signal is corrected such that it ties in the threshold range (such as between 47 percent to 53 percent), and it is further corrected by the second stage to achieve a 50 percent duty cycle. It should be noted that in the first stage, two correcting loops for the duty cycle corrections are formed. For example, a first loop is formed between the first filter 250, the first feedback circuit 230 and the first transistor 212 for controlling/changing the rise time of the output clock and a second loop is formed between the first filter 250, the second feedback circuit 260 and the second transistor 214 for controlling/changing the fall time of the output clock, for correcting the duty cycle. It should also be appreciated that for any input duty cycle, at least one of the loop is in saturated state; and by selecting different values of the first and second threshold levels, a hysteresis is created that insures that there is no interference between the functioning of the two loops of the first stage. It should also appreciated that the components used in the various embodiments of the present technology and their operation are analog in nature, thus lowering the current consumption.

Although the present technology has been described with reference to specific exemplary embodiments, it is noted that various modifications and changes may be made to these embodiments without departing from the broad spirit and scope of the present technology. For example, the various systems, modules, etc., described herein may be enabled and operated using hardware circuitry (e.g., complementary metal oxide semiconductor (CMOS) based logic circuitry), firmware, software and/or any combination of hardware, firmware, and/or software (e.g., embodied in a machine readable medium). For example, the various modules and methods may be embodied using transistors, logic gates, and electrical circuits (e.g., application specific integrated circuit (ASIC) circuitry and/or in Digital Signal Processor (DSP) circuitry).

Also, techniques, subsystems and methods described and illustrated in the various embodiments as discrete or separate may be combined or integrated with other systems, modules, techniques, or methods without departing from the scope of the present technology. Other items shown or discussed as directly coupled or connected with one another, or as directly communicating with each other, may be communicatively associated through some interface or device, such that the items may no longer be considered directly coupled or connected with one another, or directly communicating with each other, but may still be indirectly communicatively associated and in communication, whether electrically, mechanically, or otherwise, with one another. Other examples of changes, substitutions, and alterations ascertainable by one skilled in the art, upon studying the exemplary embodiments disclosed herein, may be made without departing from the spirit and scope of the present technology.

It should be noted that reference throughout this specification to features, advantages, or similar language does not imply that all of the features and advantages should be or are in any single embodiment. Rather, language referring to the features and advantages may be understood to mean that a specific feature, advantage, or characteristic described in connection with an embodiment may be included in at least one embodiment of the present technology. Thus, discussions of the features and advantages, and similar language, throughout this specification may, but do not necessarily, refer to the same embodiment. Various embodiments of the present disclosure, as discussed above, may be practiced with steps and/or operations in a different order, and/or with hardware elements in configurations which are different than those which are disclosed. Therefore, although the technology has been described based upon these exemplary embodiments, it is noted that certain modifications, variations, and alternative constructions may be apparent and well within the spirit and scope of the technology.

Although various exemplary embodiments of the present technology are described herein in a language specific to structural features and/or methodological acts, the subject matter defined in the appended claims is not necessarily limited to the specific features or acts described above. Rather, the specific features and acts described above are disclosed as exemplary forms of implementing the claims.

What is claimed is:

1. A duty cycle correction circuit, comprising:
a first set of inverters coupled in series, each inverter comprising a first transistor and a second transistor, a first inverter in the series comprising an output terminal and configured to receive a clock signal, a signal transition at the output terminal having a rise time and a fall time and a last inverter in the series configured to generate a first output clock signal having a first corrected duty cycle at an output of the last inverter;
a first filter coupled with the output of the last inverter, the first filter configured to generate a first direct current (DC) voltage signal at an output of the first filter, the first DC voltage signal generated in response to the first output clock signal received from the output of the last inverter;
a first feedback circuit coupled with the output of the first filter and the first transistor of the first inverter, the first feedback circuit configured to control the rise time, based on a comparison of the first DC voltage signal and a first threshold voltage, to thereby correct the duty cycle; and
a second feedback circuit coupled with the output of the filter and the second transistor of the first inverter, the second feedback circuit configured to control the fall time based on a comparison of the first DC voltage signal and a second threshold, voltage, to thereby further correct the duty cycle.

2. The duty cycle correction circuit of claim 1, wherein the first feedback circuit comprises:
a first amplifier comprising a first input terminal, a second input terminal and a first output terminal, the first input terminal coupled with the first threshold voltage, the second input terminal coupled with the output of the first filter to receive the first DC voltage signal; and
a third transistor comprising a first terminal, a second terminal and a third terminal, the first terminal coupled with the first output terminal of the first amplifier, the second terminal coupled with a power supply terminal and the third terminal coupled with the first transistor to provide a power supply voltage to the first transistor of the first inverter, wherein the third transistor is configured to increase the rise time of the signal transition at the output terminal of the first inverter based on a voltage at the first terminal of the third transistor.

3. The duty cycle correction circuit of claim 2, wherein the first transistor is a P-channel Metal Oxide Semiconductor (PMOS) transistor, the second transistor is a N-channel Metal Oxide Semiconductor (NMOS) transistor, the third transistor is a PMOS transistor, the first terminal is a gate terminal, the second terminal is a source terminal, and the third terminal is a drain terminal.

4. The duty cycle correction circuit of claim 2, wherein the second feedback circuit comprises:
a second amplifier comprising a third input terminal, a fourth input terminal and a second output terminal, the third input terminal coupled with the second threshold voltage, the fourth input terminal coupled with the output of the first filter to receive the first DC voltage signal; and
a fourth transistor comprising a fourth terminal, a fifth terminal and a sixth terminal, the fourth terminal coupled with the second output terminal of the second amplifier, the fifth terminal coupled with a voltage ground terminal and the sixth terminal coupled with the second transistor of the first inverter to provide a voltage ground reference to the second transistor of the first inverter, wherein the fourth transistor is configured to increase the fall time of the signal transition at the output terminal of the first inverter based on a voltage at the fourth terminal.

5. The duty cycle correction circuit of claim 4, wherein the first transistor is a P-channel Metal Oxide Semiconductor (PMOS) transistor, the second transistor is a N-channel Metal Oxide Semiconductor (NMOS) transistor, the fourth transistor is a NMOS transistor, the fourth terminal is a gate terminal, the fifth terminal is a source terminal, and the sixth terminal is a drain terminal.

6. The duty cycle correction circuit of claim 4, further comprising:
a first capacitor coupled between a power supply terminal and the first output terminal of the first amplifier; and
a second capacitor coupled between the voltage ground terminal and the second output terminal of the second amplifier.

7. The duty cycle correction circuit of claim 1, further comprising:
a second set of inverters coupled in series, a first inverter of the second set of inverters in the series receiving the first output clock signal and a last inverter of the second set of inverters in the series configured to generate a second output clock signal having a second corrected duty cycle at an output of the last inverter of the second set of inverters;
a second filter coupled with the output of the last inverter of the second set of inverters, the second filter configured to generate a second DC voltage signal at an output of the second filter in response to the second output clock signal received from the output of the last inverter of the second set of inverters;
a third amplifier comprising a fifth input terminal, a sixth input terminal and a third output terminal, the fifth input terminal coupled with a third threshold voltage, the sixth input terminal coupled with the output of the second filter to receive the second DC voltage signal;
a fifth transistor comprising a seventh terminal, an eighth terminal and a ninth terminal, the seventh terminal coupled with the third output terminal of the third amplifier, the eighth terminal coupled with a power supply terminal and the ninth terminal coupled with a first transistor of the first inverter of the second set of inverters, the fifth transistor configured to increase a rise time of a signal transition at the output terminal of the first inverter of the second set of inverters based on a voltage at the seventh terminal; and
a sixth transistor having a tenth terminal, an eleventh terminal and a twelfth terminal, the tenth terminal coupled with the third output terminal of the third amplifier, the eleventh terminal coupled with a voltage ground terminal and the twelfth terminal coupled with a second transistor of the first inverter of the second set of inverters, the sixth transistor configured to increasing a fall time of a signal transition at the output terminal of the first inverter of the second set of inverters based on a voltage at the tenth terminal.

8. The duty cycle correction circuit of claim 7, wherein each of the first threshold voltage, the second threshold voltage and the third threshold voltage is a function of a power supply voltage or a constant voltage.

9. A duty cycle correction circuit, comprising:
a first inverter and a second inverter coupled in series, each inverter comprising a first transistor and a second transistor, the first inverter comprising an output terminal and configured to receive a clock signal, a signal transition at the output terminal having a rise time and a fall time, and the second inverter configured to generate a first output clock signal having a first corrected duty cycle at an output of the second inverter;
a first filter coupled with the output of the second inverter, the first filter configured to generate a first direct current (DC) voltage signal at an output of the first filter in response to the first output clock signal;
a first amplifier having a first input terminal, a second input terminal and a first output terminal, the first input terminal coupled with a first threshold voltage, the second input terminal coupled with the output of the first filter to receive the first DC voltage signal;
a third transistor comprising a first terminal, a second terminal and a third terminal, the first terminal coupled with the first output terminal of the first amplifier, the second terminal coupled with a power supply terminal and the third terminal coupled with the first transistor of the first inverter to provide a power supply voltage to the first transistor of the first inverter, wherein the third transistor is configured to increase the rise time of the signal transition at the output terminal of the first inverter based on a voltage at the first terminal;
a second amplifier comprising a third input terminal, a fourth input terminal and a second output terminal, the third input terminal coupled with a second threshold voltage, the fourth input terminal coupled with the output of the first filter to receive the first DC voltage signal; and
a fourth transistor comprising a fourth terminal, a fifth terminal and a sixth terminal, the fourth terminal coupled with the second output terminal of the second amplifier, the fifth terminal coupled with a voltage ground terminal and the sixth terminal coupled with the second transistor of the first inverter, wherein the fourth transistor is configured to increase the fall time of the signal transition at the output terminal of the first inverter based on a voltage at the fourth terminal.

10. The duty cycle correction circuit of claim 9, wherein the first transistor is a P-channel Metal Oxide Semiconductor (PMOS) transistor, the second transistor is a N-channel Metal Oxide Semiconductor (NMOS) transistor, the third transistor is a PMOS transistor, the first terminal is a gate terminal, the second terminal is a source terminal, the third terminal is a drain terminal, the fourth transistor is a NMOS transistor, the fourth terminal is a gate terminal, the fifth terminal is a source terminal, and the sixth terminal is a drain terminal.

11. The duty cycle correction circuit of claim 9, further comprising:
a first capacitor coupled between the power supply terminal and the first output terminal of the first amplifier; and
a second capacitor coupled between the voltage ground terminal and the second output terminal of the second amplifier.

12. The duty cycle correction circuit of claim 9, further comprising:
a third inverter and a fourth inverter coupled in series, the third inverter configured to receive the first output clock signal from the output of the second inverter, the fourth inverter configured to provide a second output clock signal comprising a second corrected duty cycle at an output of the fourth inverter;
a second filter coupled with the output of the fourth inverter, the second filter configured to generate a second DC voltage signal at an output of the second filter, the second DC voltage signal generated in response to the second output clock signal received from the output of the fourth inverter;
a third amplifier comprising a fifth input terminal, a sixth input terminal and a third output terminal, the fifth input terminal coupled with a third threshold voltage, the sixth input terminal coupled with the output of the second filter to receive the second DC voltage signal;
a fifth transistor comprising a seventh terminal, an eighth terminal and a ninth terminal, the seventh terminal coupled with the third output terminal of the third amplifier, the eighth terminal coupled with the power supply terminal and the ninth terminal coupled with a first transistor of the third inverter to provide the power supply voltage to the first transistor of the third inverter, wherein the fifth transistor is configured increase a rise time of a signal transition at the output of the third inverter based on a voltage at the seventh terminal; and
a sixth transistor comprising a tenth terminal, an eleventh terminal and a twelfth terminal, the tenth terminal coupled with the third output terminal of the third amplifier, the eleventh terminal coupled with the voltage ground terminal and the twelfth terminal coupled with a second transistor of the third inverter to provide a voltage ground reference to the second transistor of the first inverter, wherein the sixth transistor is configured to increase a fall time of the signal transition at the output of the third inverter based on a voltage at the tenth terminal.

13. The duty cycle correction circuit of claim 9, wherein each of the first threshold voltage, the second threshold voltage and the third threshold voltage is a function of a power supply voltage or a constant voltage.

14. A duty cycle correction circuit, comprising:
a first stage configured to generate a first output clock signal having a first corrected duty cycle in response to a clock signal, the first stage comprising:
a first set of inverters coupled in series, a first inverter in the series comprising an output terminal and configured to receive the clock signal, a signal transition at the output terminal of the first inverter having a rise time and a fall time, and a last inverter in the series configured to generate the first output clock signal at an output of the last inverter;
a first filter coupled with the output of the last inverter, the first filter configured to generate a first direct current (DC) voltage signal at an output of the first filter in response to the first output clock signal received from the output of the last inverter;
a first feedback circuit coupled with the output of the first filter and a first transistor of the first inverter; and
a second feedback circuit coupled with the output of the first filter and a second transistor of the first inverter, wherein the first feedback circuit is configured to control the rise time based on a comparison of the first DC voltage signal and a first threshold voltage and the second feedback circuit is configured to control the fall time based on a comparison of the first DC voltage signal and a second threshold voltage for generating the first output clock signal having the first corrected duty cycle; and
a second stage configured to receive the first output clock signal and generate a second output clock signal having a second corrected duty cycle, the second stage comprising:
a second set of inverters coupled in series, a first inverter of the second set of inverters comprising an output terminal and configured to receive the first output clock signal, a signal transition at the output terminal of the first inverter of the second set of inverters having a rise time and a fall time, and a last inverter of the second set of inverters in the series configured to generate the second output clock signal at an output of the last inverter of the second set of inverters;
a second filter coupled with the output of the last inverter of the second set of inverters, the second filter configured to generate a second DC voltage signal at an output of the second filter in response to the second output clock signal received from the output of the last inverter of the second set of inverters; and
a third feedback circuit configured to control the rise time and the fall time of the signal transition at the output terminal of the first inverter of the second set of inverters based on a comparison of the second DC voltage signal and a third threshold voltage for generating the second output clock signal having the second corrected duty cycle.

15. The duty cycle correction circuit of claim 14, wherein the first feedback circuit comprises:
a first amplifier comprising a first input terminal, a second input terminal and a first output terminal, the first input terminal coupled with the first threshold voltage, the second input terminal coupled with the output of the first filter to receive to the first DC voltage signal; and
a third transistor comprising a first terminal, a second terminal and a third terminal, the first terminal coupled with the first output terminal of the first amplifier, the second terminal coupled with a power supply terminal and the third terminal coupled with the first transistor of the first inverter to provide a power supply voltage to the first transistor of the first inverter, wherein the third transistor is configured to increase the rise time of the signal transition at the output terminal of the first inverter of the first set of inverters based on a voltage at the first terminal.

16. The duty cycle correction circuit of claim 15, wherein the first transistor is a P-channel Metal Oxide Semiconductor (PMOS) transistor, the second transistor is a N-channel Metal Oxide Semiconductor (NMOS) transistor, the third transistor is a PMOS transistor, the first terminal is a gate terminal, the second terminal is a source terminal, and the third terminal is a drain terminal.

17. The duty cycle correction circuit of claim 14, wherein the second feedback circuit comprises:
a second amplifier comprising a third input terminal, a fourth input terminal and a second output terminal, the third input terminal coupled with the second threshold voltage, the fourth input terminal coupled with the output of the first filter to receive the first DC voltage signal; and
a fourth transistor comprising a fourth terminal, a fifth terminal and a sixth terminal, the fourth terminal coupled with the second output terminal of the second amplifier, the fifth terminal coupled with a voltage ground terminal and the sixth terminal coupled with the second transistor of the first inverter to provide the voltage ground reference to the second transistor of the first inverter, wherein the fourth transistor is configured to increase the fall time of the signal transition at the output terminal of the first inverter of the first set of inverters based on a voltage at the fourth terminal.

18. The duty cycle correction circuit of claim 17, wherein the first transistor is a P-channel Metal Oxide Semiconductor (PMOS) transistor, the second transistor is a N-channel Metal Oxide Semiconductor (NMOS) transistor, the fourth transistor is a NMOS transistor, the fourth terminal is a gate terminal, the fifth terminal is a source terminal, and the sixth terminal is a drain terminal.

19. The duty cycle correction circuit of claim 14, wherein the third feedback circuit comprises:
a third amplifier comprising a fifth input terminal, a sixth input terminal and a third output terminal, the fifth input terminal coupled with a third threshold voltage, the sixth input terminal coupled with the output of the second filter to receive the second DC voltage signal;
a fifth transistor comprising a seventh terminal, an eighth terminal and a ninth terminal, the seventh terminal coupled with the third output terminal of the third amplifier, the eighth terminal coupled with a power supply terminal and the ninth terminal coupled with a first transistor of the first inverter of the second set of inverters, the fifth transistor configured to increase the rise time of the signal transition at the output terminal of the first inverter of the second set of inverters based on a voltage at the seventh terminal; and
a sixth transistor comprising a tenth terminal, an eleventh terminal and a twelfth terminal, the tenth terminal coupled with the third output terminal of the third amplifier, the eleventh terminal coupled with a voltage ground terminal and the twelfth terminal coupled with a second transistor of the First inverter of the second set of inverters, the sixth transistor configured to increase the fall time of the signal transition at the output terminal of the first inverter of the second set of inverters based on a voltage at the tenth terminal.

20. The duty cycle correction circuit of claim 14, wherein each of the first threshold voltage, the second threshold voltage and the third threshold voltage is a function of a power supply voltage or a constant voltage.
